(19) United States
(12) Patent Application Publication
(10) Pub. No.: US 2007/0099372 A1
(43) Pub. Date: May 3, 2007

(54) Device having active regions of different depths

(76) Inventors: Sailesh Chittipeddi, Irvine, CA (US); Seungmoo Choi, Newport Beach, CA (US)

Correspondence Address: MENDELSOHN & ASSOCIATES, P.C., 1500 JOHN F. KENNEDY BLVD., SUITE 405, PHILADELPHIA, PA, 19102, US

(21) Appl. No.: 11/590,246

(22) Filed: Oct. 31, 2006

Related U.S. Application Data
(60) Provisional application No. 60/731,902, filed on Oct. 31, 2005.

(51) Int. Cl. H01L 21/8238; H01L 21/8242; H01L 29/788

(52) U.S. Cl. 438/199; 438/243; 257/315

(57) ABSTRACT

An SOI device having SOI layers at two or more different depths below the surface of active regions of the device. Transistors for high-speed digital applications may be formed in the shallower active regions and RF power or high-voltage transistors may be formed in the deeper active regions. In one embodiment, the shallower active regions are fully-depleted while the deeper active regions are partially-depleted.

### CROSS-REFERENCE TO RELATED APPLICATIONS

This application claims the benefit of the filing date of U.S. provisional application No. 60/731,902, filed on 31 Oct. 2005 as attorney docket no. Chittipeddi 98-33.

### BACKGROUND OF THE INVENTION

Silicon-on-insulator (SOI) substrates provide better electrical isolation (known as vertical isolation) between active devices (e.g., transistors) and an underlying substrate than conventional tub or well isolation techniques. An SOI substrate comprises a thin buried layer of a dielectric (typically silicon dioxide) disposed in the semiconductor substrate with an overlying active semiconductor layer in which active devices are formed. Additionally, vertical dielectric trenches can be formed in the active layer, extending from an upper surface of the active layer to the underlying buried oxide layer, to provide additional device isolation. Dielectric isolation eliminates “latch-up” in CMOS devices and reduces the effects of parasitic capacitances between active devices, resulting in faster transistor switching speeds.

### SUMMARY OF THE INVENTION

In one embodiment of the invention, a device comprises a first region having a buried insulator layer at a first depth below a substrate surface, and a second region having a buried insulator layer at a second depth below the substrate surface. The first depth is greater than the second depth.

In accordance with another embodiment of the invention, a process for forming a silicon-on-insulator substrate comprises the steps of providing a semiconductor substrate, masking a region of the substrate to expose a first substrate region, implanting an insulator-forming species to a first depth in the first substrate region, masking a second region of the substrate to expose a second substrate region, implanting an insulator-forming species to a second depth in the second substrate region, and annealing the semiconductor substrate. The first depth is not equal to the second depth.

In accordance with still another embodiment of the invention, a process for forming a silicon-on-insulator substrate comprises the steps of providing a substrate including a buried insulator layer at a first depth below a surface of the substrate, masking a region of the substrate to expose a substrate region, implanting a insulator-forming species in the substrate region to form a buried insulator region that is adjacent the buried insulator layer and at a second depth less than the first depth, and annealing the substrate.

### BRIEF DESCRIPTION OF THE FIGURES

The aspects, features, and advantages of the present invention are best understood from the following detailed description and appended claims when read in conjunction with the accompanying figures in which like reference numerals identify similar or identical elements. It is emphasized that, according to common practice, the various features of the figures are not to scale. On the contrary, the dimensions of the various features are arbitrarily expanded or reduced for clarity.

FIG. 1 is a cross-section view of an SOI substrate with active devices formed therein;

FIG. 2 is a cross-section view of SOI substrate with active devices formed therein and including lateral isolation;

FIG. 3 is a cross-section view of an SOI substrate with a fully-depleted active layer having an active device formed therein;

FIG. 4 is a cross-section view of an SOI substrate with a partially-depleted active layer having an active device formed therein;

FIG. 5 is a cross-section view of an SIMOX SOI substrate with a buried oxide layer at different depths below the surface of the active layer;

FIG. 6 is a cross-section view of a bonded SOI substrate with a buried oxide layer at different depths below the surface of the active layer; and

FIG. 7 is a cross-section view of the bonded SOI substrate with a buried oxide layer at different depths below the surface of the active layer and having transistors formed in the active layer.

### DETAILED DESCRIPTION

For purposes of this description and unless explicitly stated otherwise, each numerical value and range should be interpreted as being approximate as if the word “about” or “approximately” preceded the value of the value or range. Further, reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

An SOI substrate (wafer) is formed according to either a separation by implantation of oxygen (SIMOX) process or a bonded substrate process. A SIMOX process implants oxygen into a conventional bulk substrate. Controlling the implant energy controls the depth of the buried oxide layer and, thus, a thickness of the oxygen-free active semiconductor layer overlying the buried oxide layer. After implantation, the substrate is thermally annealed to repair active area damage caused by the oxygen implantation and to form an oxide layer from the implanted oxygen. It is in the active semiconductor layer that active devices, such as MOSFETs, are formed. For further details on SIMOX, refer to U.S. Pat. No. 4,676,841 (Celler), assigned to the same assignee as this application, and incorporated herein by reference in its entirety. It is understood, however, that alternative insulator-forming species, such as nitrogen or a combination of nitrogen and oxygen, may be implanted in silicon and then annealed to form a buried insulator layer. Further, iron may be implanted in a III/V compound substrate, such as GaAs, to form the buried insulator layer.

In a substrate bonding process (also referred to as wafer bonding), two conventional semiconductor substrates each having an insulator layer (typically oxidized silicon) on the surface thereof are bonded together along the surface of the insulator layers by subjecting the substrates to a compressive force in an elevated temperature environment. The joined substrates are then annealed to make permanent the insulator layer bonding in the buried layer. Thus, the joined insulator surface layers together form the buried insulator layer in the SOI substrate. One substrate may be the thinner of the two substrates or one substrate may be thinned by chemical-mechanical polishing (CMP) after the substrates are bonded and annealed. The thinner semiconductor substrate forms the active semiconductor layer in which active devices are formed. For further details on SOI bonded substrates, refer to U.S. Pat. No. 5,366,924 (Easter et al.), assigned to the same assignee as this application, and incorporated herein by reference in its entirety. Similar to that discussed above regarding implanting and annealing to form a buried insulator layer, any insulator-forming species, such as nitrogen, oxygen, or a combination of nitrogen and oxygen, may be used to form the insulator layer on the silicon substrates prior to bonding.

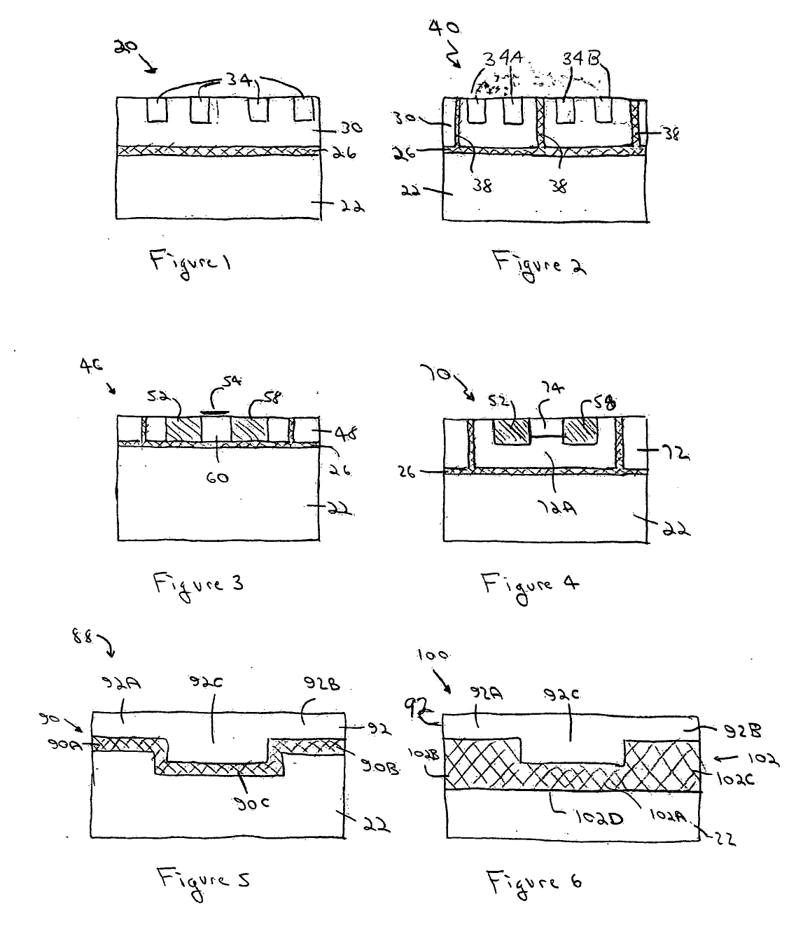

FIG. 1 illustrates an SOI substrate 20 (formed either by implanting oxygen or by substrate bonding), comprising in stacked relation, an underlying semiconductor substrate 22, a buried silicon dioxide layer 26, and an active semiconductor layer 30 in which portions of active devices 34 have been formed. The portions 34 are typically heavily doped (e.g., more than about 10¹⁸ dopant atoms/cm³) drain and source regions of MOSFETs or base/emitter/collector portions of bipolar transistors.

The SOI substrate 40 of FIG. 2 illustrates the use of substantially vertical isolation trenches 38 in active layer 30 to provide lateral isolation between the active device portions 34A, 34B. Typically, the trenches 38 are completely filled with a dielectric material, such as an oxide and/or nitride. Alternatively, the trenches are partially filled with at least one layer of the above dielectric material and then filled with polysilicon. For further details on trench isolation, refer to U.S. Pat. No. 5,373,180 (Hillenius et al.), assigned to the same assignee as this application, and incorporated herein by reference in its entirety.

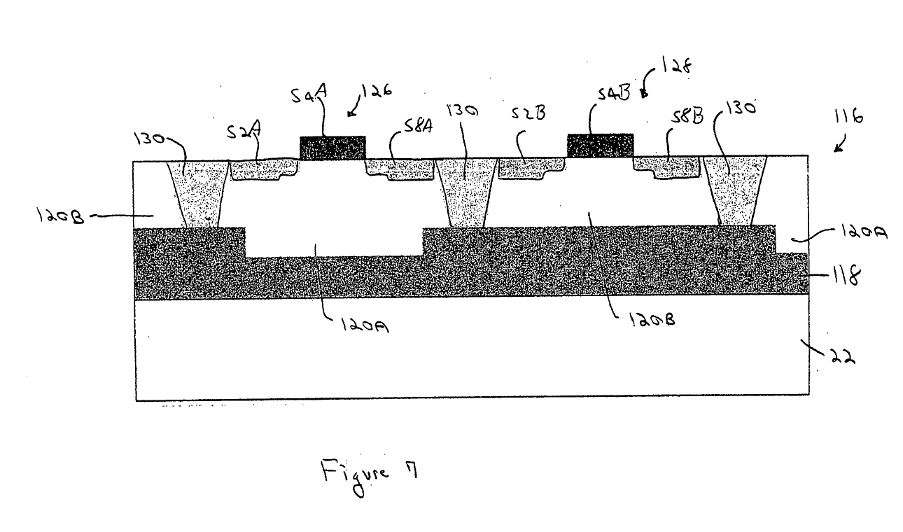

Further device operational improvements may be realized by controlling a thickness of the active layer 30 to achieve either full or partial depletion of the layer 30. A fully-depleted layer is characterized herein as a lightly or moderately doped layer (e.g., less than about 10¹⁸ dopant atoms/cm³) having substantially no carriers (electrons and/or holes) therein under normal bias voltage conditions. Similarly, a partially-depleted layer has at least some of the carriers present in the layer, the carries typically being concentrated between fully-depleted portions of the layer and where the layer meets a buried oxide layer. For heavily doped layers (e.g., greater than about 10¹⁸ dopant atoms/cm³, such as a MOSFET source and drain), substantially no depletion occurs. The structural differences of a semiconductor device having a fully-depleted layer and having a partially-depleted layer are illustrated in FIGS. 3 and 4, respectively.

In FIG. 3, an SOI substrate 46 comprises a fully-depleted active layer 48, typically having a thickness in a range of between about 10 nm and about 100 nm. As illustrated in FIG. 3, a MOSFET comprising a source 52, a gate 54, and a drain 58 is formed in the fully-depleted active layer 48 overlying the buried oxide layer 26. An inverted channel region 60 under the gate 54 extends from the surface of the fully-depleted active region 48 to the buried silicon dioxide layer 26.

An SOI substrate 70 of FIG. 4 comprises a partially-depleted active layer 72 with a thickness of between about 100 nm and about 1000 nm. An inverted channel region 74 under a gate (not shown) extends from the surface of layer 72 toward the buried oxide layer 26, but a sub-region 72A of the active layer 72 remains in an uninverted state.

It is known that a fully-depleted SOI active layer, such as that shown in FIG. 3, presents a low current leakage characteristic and is appropriate for forming high-speed switching transistors. The fully-depleted active layer is therefore suitable for fabrication of high-speed digital devices. However, a fully-depleted layer might not be suitable for RF or high-voltage applications. Instead, a partially-depleted layer, such as that shown in FIG. 4, is typically used because devices formed in a partially-depleted layer exhibit higher output conductance and have a higher breakdown voltage capability than similar devices formed in a fully-depleted active layer.

A typical SOI substrate comprises either a fully-depleted layer or a partially-depleted layer. Two or more separate SOI substrates (such as those shown in FIGS. 3 and 4) are typically used to implement circuits requiring both fully-depleted and partially-depleted active devices. It is therefore desirable to have fully-depleted and partially-depleted regions formed on the same SOI substrate.

One embodiment of the invention is shown in FIG. 5 where an SOI substrate 88 has shallow buried oxide layers 90A and 90B, a deep buried oxide layer 90C, and an active layer 92. The active layer 92 has fully-depleted regions 92A, 92B and a partially-depleted region 92C. The relatively low leakage, fast switching speed of fully-depleted regions 92A and 92B are suitable for forming memory and high-speed devices. The partially-depleted region 92C is better suited for the fabrication of RF power and high voltage devices.

To fabricate the embodiment of FIG. 5 and in accordance with the invention, an exemplary process using two masked oxygen implants is performed. A first masked implant forms the deep buried oxide layer 90C (regions of the substrate overlying the shallow buried oxide layers 90A and 90B are masked) using an implant energy of between about 500 keV and about 5 MeV at an implant dose of greater than or equal to about 10¹⁶/cm². A second masked implant forms the shallow buried oxide layers 90A and 90B (a region of the substrate overlying the deep buried oxide layer 90C is masked) using an implant energy of between about 100 keV and about 500 keV at an implant dose of greater than or equal to about 10¹⁶/cm². The substrate 88 is then annealed and conventional process steps (including the possible formation of lateral isolation structures) are employed to form devices in the active layer 92. It is understood that the order of the implants may be reversed.

An alternative embodiment of the invention is shown in FIG. 6 where an SOI substrate 100 comprises a buried oxide layer 102 having a thin buried oxide region 102A, thick buried oxide regions 102B and 102C, and a flat lower surface 102D, in contrast to the stepped lower surface of the buried oxide layer 90 of FIG. 5. In active layer 92 are shallow, fully-depleted, active regions 92A, 92B and a deeper, partially-depleted, active region 92C. As stated above, other insulator-forming species may be implanted to form buried layers 90A, 90B, and 90C.

In FIG. 7, the SOI substrate 100 of FIG. 6 is shown as substrate 116 having transistors formed therein. The substrate 116 comprises a buried oxide layer 118 forming partially-depleted active regions 120A and fully-depleted active regions 120B. A MOSFET 126, here an exemplary MOSFET for RF power or high-voltage applications and comprising source, gate, and drain regions 52A, 54A, and 58A, respectively, is disposed in a partially-depleted region 120A. A MOSFET 128, here an exemplary MOSFET for high-speed digital applications and comprising source, gate, and drain regions 52B, 54B, and 58B, respectively, is disposed in a fully-depleted region 120B. The fully-depleted regions 120B also include exemplary isolation structures 130. However, it is understood that a conventional LOCOS isolation structure may be used instead of, or in conjunction with, the trench isolation structures 130. Moreover, isolation structures 130 may also or alternatively be formed in the partially-depleted active regions 120A.

To fabricate the embodiment of FIG. 6 and in accordance with the invention, the SOI substrate 100 of FIG. 6 (and substrate 116 of FIG. 7) may be formed by first bonding two substrates together, with an oxide surface layer on each, to create a buried oxide layer of uniform thickness. Alternatively, a SIMOX substrate may be used. An oxygen implant through a mask that exposes the buried oxide regions 102B and 102C implants additional oxygen in those regions to create a thicker buried oxide layer within the regions 102B and 102C. The implant energy is between about 100 keV and about 500 keV at an implant dose of greater than or equal to about 10¹⁶/cm². The substrate 100 is then annealed to form in the active layer 92 the shallow, fully-depleted, active regions 92A, 92B and the deeper, partially-depleted, active region 92C. Conventional processing steps (including the possible formation of lateral isolation structures) are then employed to form active devices in the regions 92A, 92B, and 92C. Also, as stated above, other insulator-forming species may be implanted to form buried layers 102A, 102B, and 102C.

While the above illustrative embodiments have an active layer with two different depths between the surface thereof and the underlying buried oxide layer, it is understood that the active layer may have more than two different depths formed from one or more insulator-forming implants.

It will be further understood that various changes in the details, materials, and arrangements of the parts which have been described and illustrated in order to explain the nature of this invention may be made by those skilled in the art without departing from the scope of the invention as expressed in the following claims.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Having described the preferred embodiment of this invention, it will now be apparent to one of skill in the art that other embodiments incorporating its concept may be used. Therefore, this invention should not be limited to the disclosed embodiment, but rather should be limited only by the spirit and scope of the appended claims.

1. An integrated device, comprising:
a first region having a buried insulator layer at a first depth below a substrate surface; and
a second region having a buried insulator layer at a second depth below the substrate surface;
wherein the first depth is greater than the second depth.

2. The device of claim 1, wherein the first region is partially-depleted and the second region is fully-depleted.

3. The device of claim 2, wherein the first depth is between about 100 and about 1000 nm.

4. The device of claim 3, wherein the second depth is between about 10 and about 100 nm.

5. The device of claim 1, further comprising at least one transistor formed in each of the first and second regions.

6. The device of claim 5, wherein the at least one transistor in the first region is an RF power transistor or a high-voltage transistor.

7. The device of claim 5, wherein the at least one transistor in the second region is a digital MOSFET.

8. The device of claim 1, further comprising at least one lateral isolation structure.

9. The device of claim 8, wherein the at least one lateral isolation structure is a trench.

10. A process for forming a silicon-on-insulator substrate, comprising:
providing a semiconductor substrate;
masking a region of the substrate to expose a first substrate region;
implanting an insulator-forming species to a first depth in the first substrate region;
masking a second region of the substrate to expose a second substrate region;
implanting an insulator-forming species to a second depth in the second substrate region, wherein the first depth is not equal to the second depth; and
annealing the semiconductor substrate.

11. The process of claim 10, further comprising forming transistors in the first and second substrate regions.

12. The process of claim 10, wherein the step of implanting an insulator-forming species to the first depth comprises implanting oxygen with an energy between about 100 and about 500 keV at a dose of at least 10¹⁶ dopant atoms/cm² and the step of implanting an insulator-forming species to the second depth comprises implanting oxygen with an energy between about 500 keV and about 5 MeV at a dose of at least 10¹⁶ dopant atoms/cm².

13. The process of claim 10, wherein the first depth is between about 10 and about 100 nm below an upper surface of the first substrate region and the second depth is between about 100 and about 1000 nm below an upper surface of the second substrate region.

14. The process of claim 10, further comprising the step of forming at least one lateral isolation structure in the first or second substrate regions.

15. The process of claim 14, wherein the at least one lateral isolation structure is a trench having a depth of approximately the first or second depth.

16. A process for forming a silicon-on-insulator substrate, comprising:
providing a substrate including a buried insulator layer at a first depth below a surface of the substrate;
masking a region of the substrate to expose a substrate region;
implanting a insulator-forming species in the substrate region to form a buried insulator region that is adjacent the buried insulator layer and at a second depth less than the first depth; and
annealing the substrate.

17. The process of claim 16, further comprising forming transistors in the substrate.

18. The process of claim 16, wherein the step of implanting an insulator-forming species in the substrate region comprises implanting oxygen with an energy between about 100 and about 500 keV at a dose of at least 10¹⁶ dopant atoms/cm².

19. The process of claim 16, further comprising the step of forming at least one lateral isolation structure in the substrate.

20. The process of claim 19, wherein the at least one lateral isolation structure is a trench.
